(19) United States
(12) Patent Application Publication
(10) Pub. No.: US 2026/0271653 A1
(43) Pub. Date: Sep. 10, 2026

(54) PROCESSING METHOD TO DISSIPATE FLUID ACCUMULATION ON A SPINNING WAFER

(71) Applicant: Tokyo Electron Limited, Tokyo (JP)

(72) Inventor: Farzam Javadpour, Austin, TX (US)

(21) Appl. No.: 19/072,471

(22) Filed: Mar. 6, 2025

(51) Int. Cl. H01L 21/67; H01L 21/02; H01L 21/311; H01L 21/3213

(52) U.S. Cl. CPC H10P 72/0424; H10P 50/283; H10P 50/667; H10P 70/23; H10P 70/27

(57) ABSTRACT

A method for processing a wafer includes receiving the wafer on a wafer holder disposed in a processing chamber including a nozzle, the nozzle disposed over the wafer at a nozzle height. The method further includes rotating the wafer at a first angular velocity, and dispensing a processing solution from the nozzle at a first flow rate over the wafer while rotating the wafer at a varying angular velocity different from the first angular velocity during a processing time. And the method further includes, during the processing time, accelerating the wafer from the first angular velocity.

### TECHNICAL FIELD

The present invention relates generally to a system and method for processing a wafer, and, in particular embodiments, to a system and method for processing a wafer to dissipate fluid accumulation on a spinning wafer.

### BACKGROUND

In semiconductor manufacturing processes, uniform etching of materials like TEOS (tetraethyl orthosilicate) across a wafer surface is desired for producing reliable semiconductor devices. Conventional wet etching processes typically involve dispensing an etchant solution onto a spinning wafer through a center nozzle. However, these processes often result in non-uniform etching patterns, particularly when the etchant solution forms a hydraulic jump-a phenomenon where fluid accumulates at a certain radial distance before releasing at higher velocity, causing turbulence and fingering patterns. This non-uniformity becomes especially pronounced for shallow etching processes, where etch non-uniformity below 2.5% is desired.

Current approaches using constant dispense rates and rotation speeds have been unable to consistently achieve the desired etch uniformity across the wafer surface. The development of hydraulic jumps during center liquid dispense creates zones of disturbed flow, particularly in a disturbance region between the hydraulic jump and the wafer edge, leading to non-uniform etchant contact with the wafer surface. These challenges persist across a wide range of rotational speeds and dispense flow rates, resulting in both radial and azimuthal etch non-uniformity that impacts semiconductor device yield and performance.

### SUMMARY

In accordance with an embodiment of this disclosure, a method for processing a wafer includes receiving the wafer on a wafer holder disposed in a processing chamber including a nozzle, the nozzle disposed over the wafer at a nozzle height. The method further includes rotating the wafer at a first angular velocity, and dispensing a processing solution from the nozzle at a first flow rate over the wafer while rotating the wafer at a varying angular velocity different from the first angular velocity during a processing time. And the method further includes, during the processing time, accelerating the wafer from the first angular velocity.

In accordance with another embodiment of this disclosure, a method for processing a wafer includes receiving the wafer on a wafer holder disposed in a processing chamber including a nozzle, the nozzle disposed over the wafer at a nozzle height, the wafer including a wafer radius. The method further includes processing the wafer using a first set of processing parameters during a processing time, the processing including rotating the wafer at a first angular velocity and flowing a processing solution over the wafer at a first flow rate, the first set of processing parameters including the first angular velocity and the first flow rate. The method further includes, during the processing time, determining whether the processing solution has formed a fluid accumulation at a radial distance less than the wafer radius using a light detector. And the method further includes, in response to determining the processing solution has formed a fluid accumulation at a radial distance less than the wafer radius, accelerating the wafer from the first set of processing parameters to a second set of processing parameters during the processing time, the second set of processing parameters including a second angular velocity different from the first angular velocity and a second flow rate different from the first flow rate.

And in accordance with yet another embodiment of this disclosure, a system for processing a wafer includes a wafer holder disposed in a processing chamber, the processing chamber including a first window and a second window, a nozzle disposed at a configurable height over the wafer holder in the processing chamber, a light source and a light detector, the light source coupled to the first window and the light detector coupled to the second window, and a rotary drive coupled to the wafer holder. And the system further includes a controller coupled to the nozzle, the processing chamber, the light source, the light detector, the rotary drive, the wafer holder, and a memory storing instructions to be executed in the controller. The instructions when executed enable the controller to receive the wafer on the wafer holder, the nozzle disposed over the wafer at a nozzle height, the wafer including a wafer radius, and process the wafer using a first set of processing parameters during a processing time in the processing chamber, the processing including rotating the wafer at a first angular velocity using the rotary drive and flowing a processing solution from the nozzle over the wafer at a first flow rate, the first set of processing parameters including the first angular velocity and the first flow rate. The instructions when executed further enable the controller to, during the processing time, determine whether the processing solution has formed a fluid accumulation at a radial distance less than the wafer radius using the light detector, and in response to determining the processing solution has formed a fluid accumulation at a radial distance less than the wafer radius, accelerate the wafer from the first set of processing parameters to a second set of processing parameters during the processing time using the nozzle and the rotary drive, the second set of processing parameters including a second angular velocity different from the first angular velocity and a second flow rate different from the first flow rate.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1C illustrate cross-sectional views and top views of a wafer during various steps of a processing method that modifies processing parameters during the processing method to prevent hydraulic jump and improve etch uniformity in accordance with an embodiment of this disclosure;

FIGS. 2A-2B illustrate cross-sectional views and top views of a wafer during various steps of a processing method that modifies processing parameters during the processing method to prevent hydraulic jump and improve etch uniformity using a light detector in accordance with an embodiment of this disclosure;

FIGS. 3A-3B are flowcharts illustrating steps of embodiment processing methods that modify processing parameters during the corresponding processing methods to prevent hydraulic jump and improve etch uniformity in accordance with embodiments of this disclosure;

FIG. 4 is a plot illustrating etch uniformities across a wafer for different processing methods using different processing parameters in accordance with an embodiment of this disclosure;

FIG. 5 is a system diagram of a processing system capable of implementing the processing methods of FIGS. 1A-1C and FIGS. 2A-2B in accordance with embodiments of this disclosure;

FIG. 6 is a flowchart illustrating a processing method that modifies processing parameters during the processing method to prevent hydraulic jump and improve etch uniformity in accordance with an embodiment of this disclosure; and

FIG. 7 is a flowchart illustrating a processing method that modifies processing parameters during the processing method to prevent hydraulic jump and improve etch uniformity in accordance with an embodiment of this disclosure.

### DETAILED DESCRIPTION OF ILLUSTRATIVE EMBODIMENTS

In semiconductor device fabrication, achieving precise and uniform etching across an entire wafer surface remains a manufacturing challenge. Current wet etching processes that dispense etchant solutions onto spinning wafers frequently produce non-uniform material removal patterns, with etch depth variations exceeding 2.5% across the wafer surface. These variations stem from fluid dynamics phenomena, particularly the formation of hydraulic jumps where the dispensed etchant accumulates at specific radial distances before releasing at higher velocities, creating turbulent flow patterns and uneven etchant distribution. The resulting inconsistent material removal compromises semiconductor device quality, reduces manufacturing yields, and limits the ability to produce increasingly miniaturized features desired for advanced semiconductor applications. Traditional approaches using fixed rotation speeds and constant dispense rates have not successfully overcome these fluid dynamics limitations, leaving manufacturers unable to meet the stringent uniformity desires of modern semiconductor processing.

The processing method of this disclosure introduces a dynamic approach to wet etching by implementing variable processing parameters (such as rotation speeds and fluid dispense rates) during the etching process. By employing either a gradual increase in rotation speed for short processes or a sinusoidal pulsation of rotation speed for longer processes, the system can delay or prevent the formation of hydraulic jumps. This controlled variation, which can be combined with modulated dispense rates starting high, reducing to an intermediate rate, and then increasing again, effectively manages fluid distribution across the wafer surface. The process can be further enhanced through a multi-nozzle system where fluids are dispensed at different rates and variations from multiple points. These coordinated adjustments in rotation and dispense parameters significantly reduce turbulent flow patterns and ensure more uniform etchant contact with the wafer surface, ultimately achieving the sub-2.5% etch non-uniformity desired for advanced semiconductor manufacturing.

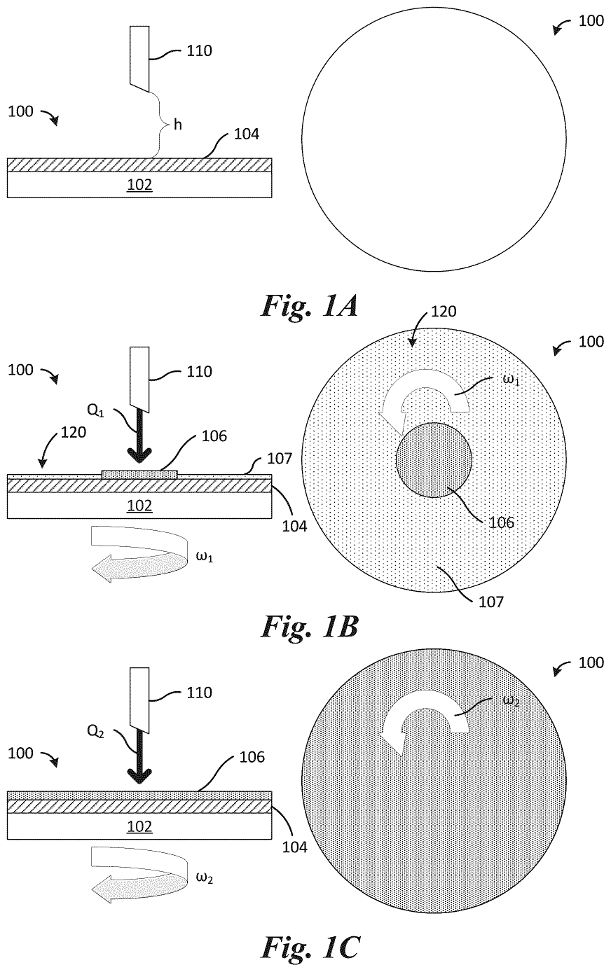

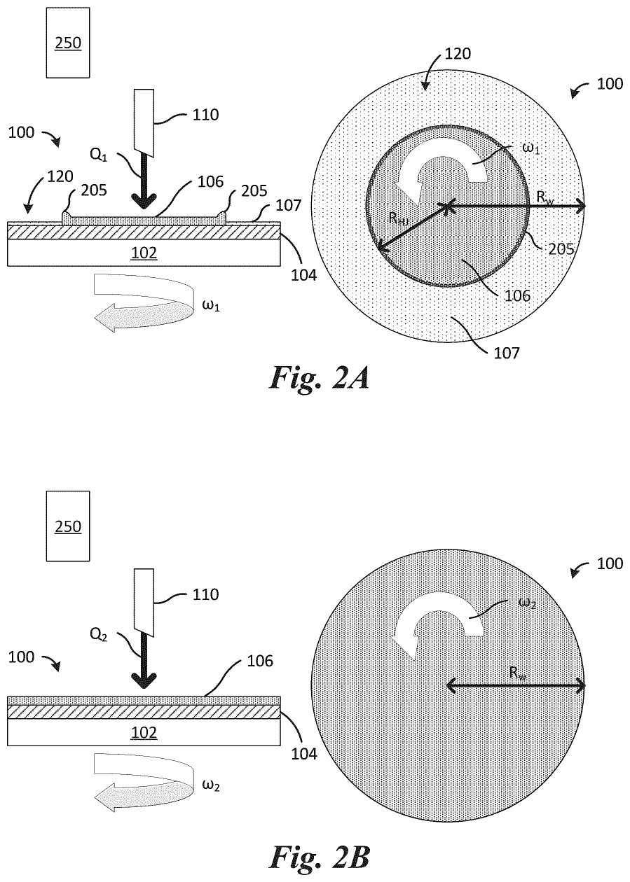

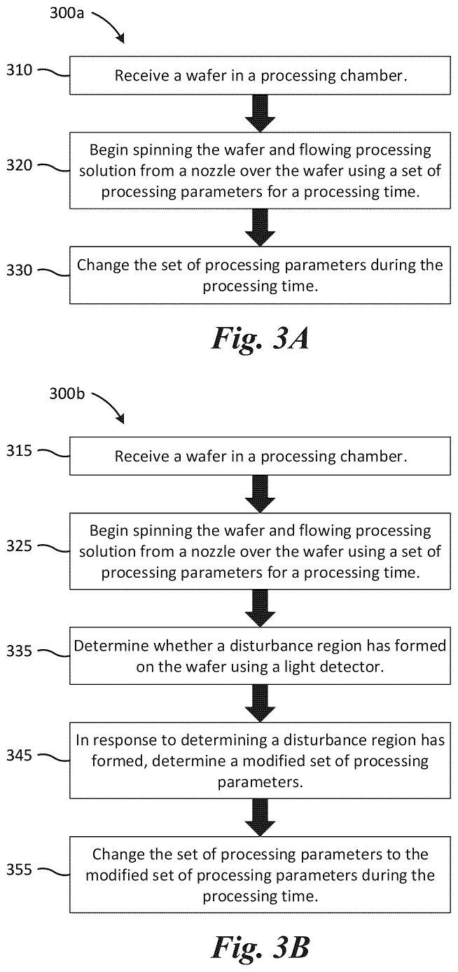

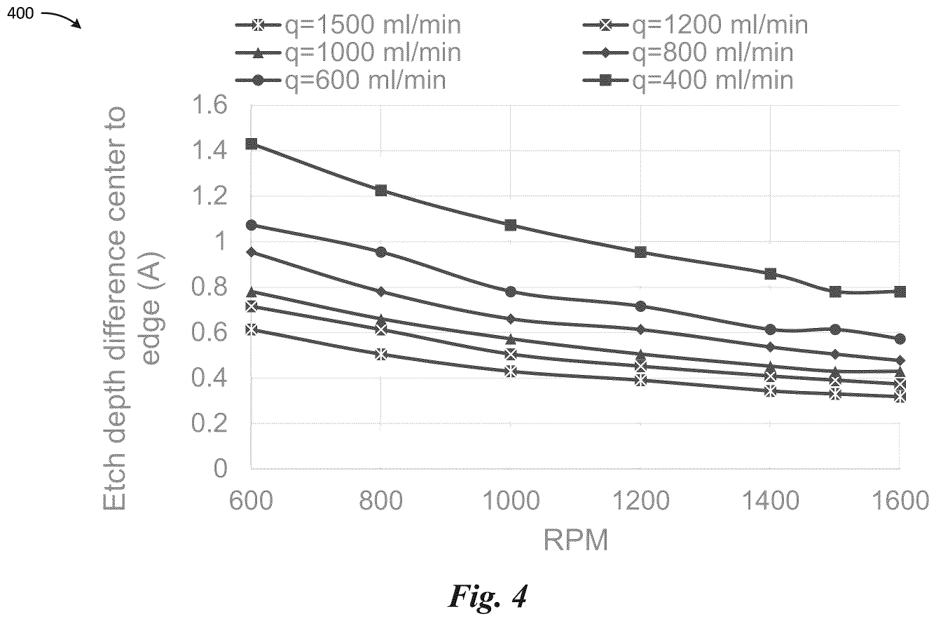

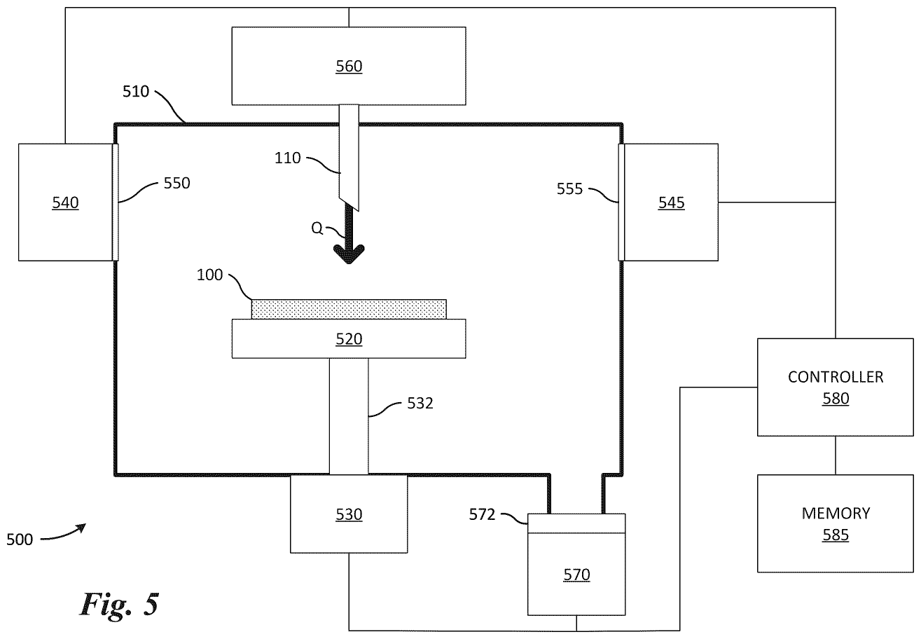

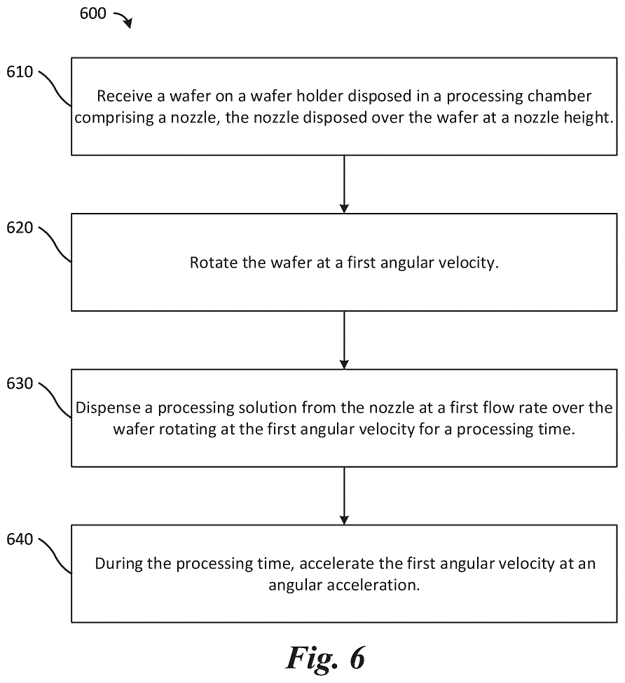

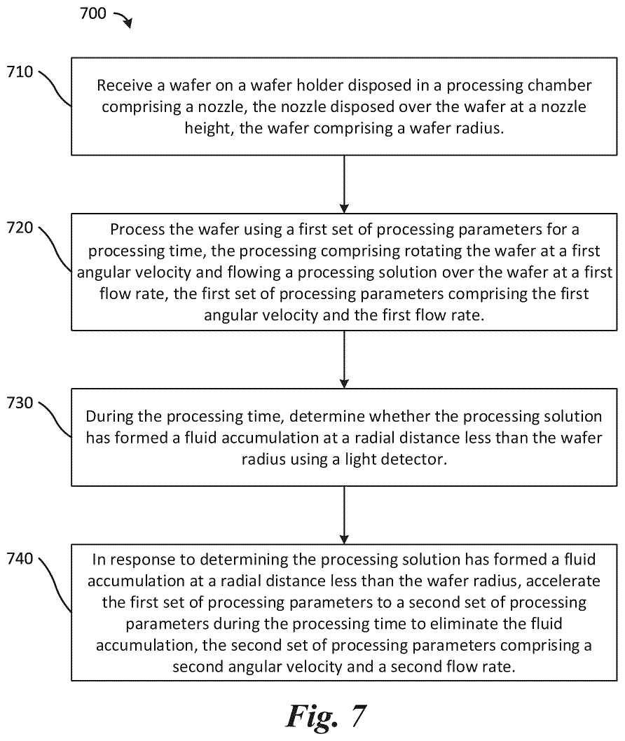

Embodiments provided below describe various methods for processing a wafer, and in particular, to methods of processing a wafer by modifying processing parameters during the process to prevent hydraulic jump and improve etch uniformity. The following description describes the embodiments. FIGS. 1A-1C describe an example processing method that prevents hydraulic jump and improves etch uniformity by modifying processing parameters during the process. FIGS. 2A-2B describe another example processing method that prevents hydraulic jump and improves etch uniformity by modifying processing parameters during the process according to monitoring by a light detector. FIGS. 3A-3B are flowcharts describing processing methods that modify processing parameters during the process, where FIG. 3A describes the processing method illustrated in FIGS. 1A-1C, and where FIG. 3B describes the processing method illustrated in FIGS. 2A-2B. A plot contrasting various etch uniformities for processing methods that use different processing parameters is illustrated in FIG. 4. FIG. 5 is a schematic diagram of a processing system which may be used to implement the processing methods of this disclosure. And the flowcharts of FIGS. 6-7 illustrate example methods of processing a wafer to prevent hydraulic jump and improve etch uniformity in accordance with embodiments of this disclosure.

FIGS. 1A-1C illustrate cross-sectional views and top views of a wafer 100 during various steps of a processing method that modifies processing parameters during the processing method to prevent hydraulic jump and improve etch uniformity in accordance with an embodiment of this disclosure.

FIG. 1A illustrates a cross-sectional view (on the left) and a top view (on the right) of a wafer 100 which may be used in the processing method of this disclosure. The wafer 100 comprises a substrate base 102, and an unprocessed layer 104 disposed over the substrate base 102. In an embodiment, the wafer 100 illustrated in FIG. 1A may be after receiving the wafer 100 in a processing system to process the unprocessed layer 104 for example. In an embodiment, the processing system may be a wet etch system configured to emit a processing solution over the wafer 100 while the wafer 100 is rotating to etch the unprocessed layer 104.

The unprocessed layer 104 may have been deposited through conventional deposition methods before the wafer 100 is received in the processing system. For example, the unprocessed layer 104 may be deposited through a suitable deposition process such as a plasma deposition process, or an atomic layer deposition (ALD) process, or a chemical vapor deposition (CVD), or a plasma-enhanced chemical vapor deposition (PECVD) process. In various embodiments, after depositing the unprocessed layer 104, a planarization process may be performed to planarize the unprocessed layer 104.

The substrate base 102 may comprise silicon, silicon oxide, or other suitable materials commonly used in semiconductor manufacturing. In various embodiments, the unprocessed layer 104 may comprise various materials depending on the specific application, such as dielectric materials, conductive materials, or semiconductor materials. For example, the unprocessed layer 104 may comprise a film stack for forming a memory device. Further, the unprocessed layer 104 may comprise multiple layers comprising various materials such as silicon dioxide, silicon nitride, phosphosilicate glass (PSG), borophosphosilicate glass (BPSG), silicon, germanium, gallium arsenide, indium phosphide, aluminum or aluminum alloys, copper, gold, silver, titanium, tungsten, titanium nitride, titanium tungsten, metal silicides, gallium nitride, indium gallium arsenide, aluminum gallium arsenide, polysilicons, or tetraethyl orthosilicate (TEOS).

In some embodiments, the unprocessed layer 104 may comprise a patterned etch mask. In those embodiments, the unprocessed layer 104 may have a pattern transferred into it through a suitable etching process in subsequent processing steps (FIGS. 1B-1C). The patterned etch mask may comprise a photosensitive material patterned through exposure to light, and subsequently used as a mask for further processing steps after patterning. In various embodiments, the patterned etch mask comprises tin (Sn), oxygen/hydroxide (O/OH), oxygen (O), or organic components (saturated/unsaturated hydrocarbon). As an example, various embodiments of the patterned etch mask comprise tin oxide, hafnium based MORs (such as hafnium oxide), zirconium based MORs (such as zirconium oxide), titanium based MORs (such as titanium oxide), or mixed metal MORs (such as hafnium zirconium oxide).

In various embodiments, the wafer 100 may be received on a wafer holder in a processing system. After receiving the wafer 100, a nozzle 110 may be centered or slightly off centered over the wafer 100 at a nozzle height (h) from the unprocessed layer 104, the nozzle 110 comprising a nozzle radius. In various embodiments, the nozzle height (h) may vary between 2 mm to 30 mm, where the nozzle radius may vary between 0.2 mm and 5 mm.

The nozzle 110 may be any suitable nozzle for emitting a processing solution over the wafer 100, such as an etching solution comprising an etchant. In one or more embodiments, multiple nozzles (such as a dual nozzle embodiment) may be used, where each nozzle may be disposed over different radial distances from the center of the wafer 100. The nozzle 110 may be configured such that a flow rate of processing solution may be controlled during the processing of the wafer 100. In various embodiments, the nozzle 110 may be capable of flowing the processing solution over the wafer 100 at flow rates between 100 mL/min and 3000 mL/min.

As described above, the wafer 100 depicted in FIG. 1A may represent an initial stage in a processing method to process the unprocessed layer 104 of the wafer 100. This configuration forms the basis for subsequent processing steps, which may comprise an etch process that rotates the wafer 100 while flowing processing solution from the nozzle 110, and a rinsing and drying process to remove the processing solution and any byproducts remaining from reactions between the processing solution and the wafer 100. The wafer 100 may be rotated at rotation speeds (or angular velocities) between 100 RPM and 3000 RPM.

FIG. 1B illustrates a cross-sectional view (on the left) and a top view (on the right) of the next step in the processing method, where conventional techniques are employed to rotate the wafer 100 while emitting a processing solution over the wafer 100 for a processing time. In the step illustrated in FIG. 1B, the nozzle 110 flows a processing solution at a first flow rate (Q₁) over the wafer 100 while rotating the wafer 100 at a first angular velocity (ω₁), where a first set of processing parameters comprises the first angular velocity (ω₁) and the first flow rate (Q₁). In one or more embodiments, the first set of processing parameters may further comprise a chamber pressure, the nozzle height (h), and a temperature of the wafer 100.

In various embodiments, the processing solution may comprise materials to etch the unprocessed layer 104 of the wafer 100. In those embodiments, the processing solution may comprise acid-based etchants, or base-based etchants. For example, the acid-based etchants may comprise hydrofluoric acid, phosphoric acid, nitric acid, sulfuric acid, or a buffered oxide etch (which uses a mixture of hydrofluoric acid and NH₄F). Further, the base-based etchants may comprise potassium hydroxide, tetramethylammonium hydroxide (TMAH), or sodium hydroxide.

During the processing time, the emitting of the processing solution at the first flow rate (Q₁) while the wafer 100 is rotating at the first angular velocity (ω₁) may form a processing solution layer 106 that extends from the center of the wafer 100 to a radial distance less than the radius of the wafer 100. This may occur for various reasons, such as solution viscosity, wafer size, and process desires. Consequently, a nonuniform processing solution layer 107 may form over the remaining surface of the wafer 100 to the edge of the wafer 100, where the nonuniform processing solution layer 107 comprises turbulent processing solution, or sparse processing solution. Additionally, the region of the wafer 100 covered by the nonuniform processing solution layer 107 is a disturbance region 120.

The disturbance region 120 comprises the nonuniform processing solution layer 107, which may be formed from the first set of processing parameters remaining constant over the processing time of the wafer 100. For example, processing solution may form a fluid accumulation at the edge of the processing solution layer 106. The processing solution may accumulate at a particular radial distance from the center of the wafer 100 and subsequently release at a higher velocity over the surface of the wafer 100, which causes turbulence and fingering and forms the disturbance region 120. The fluid accumulation and release at a higher velocity of the processing solution is a hydraulic jump, and hydraulic jump contributes to nonuniform etching of the wafer 100. If the first set of processing parameters were to remain constant during the processing time of the wafer 100, the unprocessed layer 104 may be nonuniformly processed by the processing solution, where regions of the unprocessed layer 104 in the disturbance region 120 are processed less than the regions of the unprocessed layer 104 covered by the processing solution layer 106. The processing method of this disclosure modifies the processing parameters during the processing time of the wafer 100 to prevent hydraulic jump and improve etch uniformity, which may be described using FIG. 1C below.

FIG. 1C illustrates a cross-sectional view (on the left) and a top view (on the right) of the wafer 100 after modifying the first set of processing parameters of the processing method to a second set of processing parameters during the processing time. Changing to the second set of processing parameters causes the processing solution layer 106 to completely cover the wafer 100, extending to outer edges of the wafer 100. Additionally, the processing solution layer 106 now uniformly covers the surface of the wafer 100, eliminating the disturbance region 120. And the elimination of the disturbance region 120 enables the processing method to continue to process (etch) the unprocessed layer 104 with improved uniformity for the remaining processing time.

In various embodiments, the wafer 100 may be accelerated from the first angular velocity (ω₁) to a second angular velocity (ω₂) using a constant angular acceleration. In other embodiments, the wafer 100 may be accelerated from the first angular velocity (ω₁) to the second angular velocity (ω₂) using a variational angular acceleration, such as a sinusoidal angular acceleration, which pulses the processing solution layer 106 at a processing frequency to prevent fluid accumulation and thus hydraulic jump.

In one or more embodiments, various processing parameters may be changed, such as the nozzle height (h), the angular velocity (ω), and the flow rate (Q), or combinations of these. Additionally, in those embodiments, the change to the processing parameters may be determined based on the processing time. For example, in an embodiment comprising a short processing time, the wafer 100 may be accelerated from the first angular velocity (ω₁) to a second angular velocity (ω₂) using a constant angular acceleration. And in an embodiment comprising a long processing time, the wafer 100 may be accelerated from the first angular velocity (ω₁) to the second angular velocity (ω₂) using a variational angular acceleration, such as a sinusoidal angular acceleration.

Other embodiments may utilize multiple nozzles to emit multiple streams of processing solution at different radii over the wafer 100 during the processing time. In those embodiments, the processing parameters may further comprise flow rates for each of the multiple nozzles, which may also be individually modified in the step of FIG. 1C to prevent hydraulic jump and improve etch uniformity of the wafer 100.

In various embodiments, additional processing steps may be performed to finish processing the wafer 100 after performing the steps described using FIGS. 1A-1C. For example, while maintaining the rotation of FIG. 1C, the wafer 100 may then be rinsed with a rinsing solution (such as deionized water, RCA cleaning solutions, or isopropyl alcohol) to remove the processing solution and any byproducts formed during the processing. And after the rinsing, the wafer 100 may then be spun at a high angular velocity between 1000 RPM and 3000 RPM to dry the surface of the wafer 100 through centrifugal force. In other embodiments, modifications to the processing parameters may be determined and made in real-time by monitoring the wafer 100 during processing, such as the embodiment processing method described using FIGS. 2A-2B below.

FIGS. 2A-2B illustrate cross-sectional views and top views of the wafer 100 during an embodiment processing method that modifies processing parameters during the processing method using a light detector 250 to monitor for hydraulic jump formation in accordance with an embodiment of this disclosure.

FIG. 2A illustrates a cross-sectional view (on the left) and a top view (on the right) of an alternative embodiment of the wafer 100 during the flow of the processing method of FIGS. 1A-1C, where after receiving the wafer 100 in FIG. 1A, the processing method continues to the step illustrated in FIG. 2A. In FIG. 2A, the processing method of this disclosure flows a processing solution over the wafer 100 at a first flow rate (Q₁) while rotating the wafer 100 at the first angular velocity (ω₁) for a processing time. During the processing time, a light detector 250 may be used to monitor the wafer 100 in real-time for the formation of a fluid accumulation 205 of the processing solution in the processing solution layer 106. The light detector 250 may be any suitable device for monitoring the wafer 100 in real-time during the processing time, such as a high-speed camera.

If the light detector 250 determines a fluid accumulation 205 has occurred, the light detector 250 may be used to determine changes to a first set of processing parameters based on measure properties of the wafer 100 during the step illustrated in FIG. 2A. For example, the light detector 250 may determine the fluid accumulation 205 has occurred at a radial distance (R_{HJ} in the top view) which is less than a wafer radius (R_{w} in the top view) of the wafer 100. In an embodiment, the radial distance (R_{HJ} in the top view) of the fluid accumulation 205 may be used to determine a second set of processing parameters of the wafer 100, such as a second angular velocity, a second flow rate of processing solution, accelerations for modifying the first processing parameters, a second nozzle height, a modified chamber pressure, a new temperature of the wafer 100, or combinations of these. Though the light detector 250 is illustrated above the wafer 100 in FIG. 2A, alternative embodiments may position the light detector 250 in any suitable arrangement that still enables the light detector 250 to monitor the surface of the wafer 100 for the fluid accumulation 205 during the processing method.

FIG. 2B illustrates a cross-sectional view (on the left) and a top view (on the right) of the wafer 100 after modifying the first set of processing parameters used in FIG. 2A to a second set of processing parameters determined using the light detector 250. After accelerating the first set of processing parameters to the second set of processing parameters, the processing method may continue to process the wafer 100 for the remaining portion of the processing time. For example, in wet etch embodiments, the wafer 100 may continue to be spun at the second angular velocity (ω₂) while flowing the processing solution at the second flow rate (Q₂) until the desired amount of the unprocessed layer 104 has been removed. In those embodiments, the unprocessed layer 104 forms a processed layer once etched, which may comprise a feature pattern transferred into the unprocessed layer 104 through the etching.

In various embodiments, the light detector 250 may remain monitoring the wafer 100 for any potential formations of another fluid accumulation which may be mitigated by changing the processing parameters again. As illustrated in FIG. 2B, the modification of the first set of processing parameters to flow the processing solution at a second flow rate (Q₂) and rotate the wafer 100 at a second angular velocity (ω₂) eliminated the fluid accumulation 205 and spread the processing solution layer 106 to the edge of the wafer 100 at the wafer radius (R_{w} in the top view), thus eliminating the disturbance region 120.

Both the processing method of FIGS. 1A-1C and the processing method of FIGS. 2A-2B may perform additional processing steps to finish processing the wafer 100. For example, in wet etch embodiments, the processing method may proceed to perform a rinse with rinsing solution at similar angular velocity to remove byproducts and a drying process which spins the wafer 100 at a high angular velocity to dry the wafer 100 through centrifugal force.

The processing methods described using FIGS. 1A-1C and FIGS. 2A-2B may be used to prevent hydraulic jump and improve etch uniformity. By modifying the processing parameters during the etching, the processing methods of this disclosure differ from conventional methods. The acceleration of the processing parameters during the processing time may ameliorate fluid accumulation, where the processing parameters may be gradually, or rapidly, changed or pulsed using a pulsing frequency. The embodiment processing methods of this disclosure are capable of etching wafers such that nonuniformities are below 2.5%, which is a benefit of this disclosure over conventional methods.

FIGS. 3A-3B illustrate flowcharts for two embodiment processing methods of processing a wafer by modifying processing parameters to prevent hydraulic jump and improve etch uniformity in accordance with embodiments of this disclosure.

FIG. 3A illustrates a flowchart for a method 300a of processing a wafer by modifying processing parameters during the method 300a to prevent hydraulic jump and improve etch uniformity. The method 300a begins by receiving a wafer in a processing chamber in step 310. In various embodiments, the wafer may be the wafer 100 of FIGS. 1A-1C and step 310 may be the step of the processing method described using FIG. 1A. For example, the wafer may be received in the processing chamber after forming various layers over a substrate base of the wafer and after forming a patterned etch mask over the various layers, the patterned etch mask comprising a feature pattern to be transferred to the various layers. In one or more embodiments, the processing chamber may be an etch chamber of an etching apparatus configured to perform a wet etch process, where the wafer may be received on a wafer holder of the etch chamber.

After receiving the wafer in the processing chamber, the method 300a may proceed to step 320. In step 320, the method 300a begins spinning the wafer and flowing processing solution from a nozzle over the wafer using a set of processing parameters for a processing time. In various embodiments, the set of processing parameters may comprise a first angular velocity for rotating the wafer, a first flow rate for dispensing processing solution from the nozzle, and a nozzle height that separates the end of the nozzle from a surface of the wafer. In various embodiments, step 320 of the method 300a may be the step described using FIG. 1B.

After beginning to process the wafer using the set of processing parameters in step 320, the method 300a may proceed to step 330. In step 330, the method 300a changes the set of processing parameters during the processing time. The changes to the set of processing parameters may comprise individual modifications to processing parameters or combinations of changes to multiple processing parameters, such as described above using FIG. 1C. In various embodiments, step 330 of the method 300a may be the step described using FIG. 1C.

FIG. 3B illustrates a flowchart for a method 300b of processing a wafer by modifying processing parameters during the method 300b according to monitoring by a light detector to prevent hydraulic jump and improve etch uniformity. The difference between the method 300a of FIG. 3A and the method 300b of FIG. 3B is that the method 300b of FIG. 3B uses a light detector to monitor the wafer during processing to determine a modification for the processing parameters to prevent hydraulic jump and improve etch uniformity. In FIG. 3B, the method 300b begins by receiving a wafer in a processing chamber in step 315. The wafer and the processing chamber may be as previously described for step 310 of the method 300a in FIG. 3A. In various embodiments, the wafer may be the wafer 100 of FIGS. 2A-2B, and the light detector may be the light detector 250 of FIGS. 2A-2B.

After receiving the wafer in the processing chamber, the method 300b may proceed to step 325. In step 325, the method 300b begins spinning the wafer and flowing processing solution from a nozzle over the wafer using a set of processing parameters for a processing time. Similarly, the set of processing parameters may be as described for the step of the processing method illustrated in FIG. 2A. After beginning to process the wafer using the set of processing parameters in step 325, the method 300b may proceed to step 335. In step 335, the method 300b determines whether a disturbance region has formed on the wafer using a light detector of the processing chamber. In one or more embodiments, the light detector may determine the modifications to the processing parameters using the light detector as described for the light detector 250 in FIG. 2A. Further, steps 325 and 335 of the method 300b may be the step described using FIG. 2A above.

Still referring to FIG. 3B, in response to determining a disturbance region has formed using the light detector, the method 300b determines a modified set of processing parameters in step 345. Step 345 of the method 300b may be the step described using FIG. 2A above. Additionally, the disturbance region may be the disturbance region 120 of FIG. 2A, and the light detector may monitor for a fluid accumulation, such as the fluid accumulation 205 of FIG. 2A.

And after determining the modified set of processing parameters in step 345, the method 300b proceeds to step 355. In step 355, the method 300b changes the set of processing parameters to the modified set of processing parameters during the processing time. Step 355 of the method 300b may be the step illustrated and described using FIG. 2B. Further, the changes to the set of processing parameters may be as described using FIG. 1C and FIG. 2B above, where various combinations of multiple or single parameter changes may be used to dissipate the fluid accumulation, and to more evenly distribute the processing solution over the surface of the wafer such that hydraulic jump is prevented and etch uniformity is improved.

After processing the wafer for the processing time in both methods 300a and 300b, the corresponding method may proceed to perform further processing steps to finish wet etching (or processing) the wafer. For example, various embodiments perform a rinse using a rinse solution (while rotating the wafer) followed by rotating the wafer at a high angular velocity to remove byproducts from the wet etch process and to dry the wafer. A plot which may be used to determine processing parameter modifications to achieve desired etch uniformities is described using FIG. 4 below.

FIG. 4 illustrates a plot 400 comparing etch uniformities for various processing methods that used different flow rates (q) and angular velocities (ω) to process a wafer in accordance with embodiments of this disclosure. The plot 400 shows the etch uniformities as an etch depth difference between a center region and an edge region on a wafer written as Etch depth difference center to edge. The etch uniformities are plotted with units of angstroms (Å). In the plot 400, the etch uniformities are plotted for an associated angular velocity (ω) written as rotations per minute (RPM), which is also the unit.

The plot 400 comprises various processing methods (the various lines), where each processing method corresponds to a flow rate (q) of processing solution over the wafer being processed, where the flow rates (q) have units of milliliters per minute (mL/min), and where each datapoint corresponds to a particular angular velocity. In various embodiments, the plot 400 illustrates how various combinations of different processing parameters may result in improved etch uniformity on the wafer. In one or more embodiments, the plot 400 may be used to determine modifications to processing parameters to prevent hydraulic jump and improve etch uniformity. As an example, the processing parameters, or modifications to the processing parameters may be selected such that the etch depth variation between different regions of the wafer are minimized. And the modifications to the processing parameters determined using the plot 400 of FIG. 4 may be implemented in a suitable processing system such as described using FIG. 5 below.

FIG. 5 illustrates a schematic diagram of a processing system 500, which may be used to perform the processing method of this disclosure to adjust processing parameters during the processing method to prevent hydraulic jump and improve etch uniformity on the wafer 100, as described in previous figures. The processing system 500 comprises several components designed to achieve precise control over the processing parameters used in the processing method.

The processing system 500 comprises a processing chamber 510 which houses a wafer holder 520 configured to hold the wafer 100 during the processing method of this disclosure. For example, the processing system 500 may be a wet etch apparatus configured to etch the wafer 100 using a processing solution comprising an etchant. In various embodiments, the processing chamber 510 may be an etch chamber configured to maintain a vacuum environment (or other process specifications) for the processing method.

In various embodiments, the wafer holder 520 may comprise a heater (not shown) to control the temperature of the wafer 100 during the processing method. In an embodiment, the wafer holder 520 comprises a resistive heater, where the heater (not shown) is the resistive heater. In other embodiments, the wafer holder 520 may comprise cooling elements to further control the temperature of the wafer 100 as desired during the processing method. In some embodiments, the heating and cooling elements may be parts of the processing chamber 510. In various embodiments, the wafer holder 520 may be any suitable wafer holder known in the art capable of holding the wafer 100 during the embodiment methods of this disclosure, such as an electrostatic chuck (ESC) or a vacuum chuck.

At the top of the processing chamber 510 is a solution dispensing system 560 coupled to the nozzle 110 and configured to dispense processing solution through the nozzle 110 over the wafer 100 with a controllable flow rate (Q). In various embodiments, the solution dispensing system 560 comprises reservoirs, pumps, and flow controllers to regulate and control the flow rate (Q) and timing of processing solution delivery to achieve uniform distribution across the wafer surface through centrifugal force generated by rotating the wafer 100.

The processing system 500 further comprises a light source 540 optically coupled with a first window 550 disposed on a sidewall of the processing chamber 510 to enable the light source 540 to illuminate interior regions of the processing chamber 510. Additionally, the processing system 500 comprises a light detector 545 optically coupled with a second window 555 disposed on an opposite sidewall from the first window 550 of the processing chamber 510 to enable real-time monitoring of the wafer 100 and the interior of the processing chamber 510 during the processing method.

In various embodiments, the light detector 545 may be any suitable device for monitoring fluid accumulation on the surface of the wafer 100 during the processing, such as a high-speed camera or imaging devices. In various embodiments, the light source 540 may be any suitable device for illuminating the interior of the processing chamber 510 during the processing method of this disclosure, such as a light emitting-diode (LED), a florescent light source, or a yellow light source. In similar embodiments, the first window 550 and the second window 555 may comprise the same material and may be any suitable material capable of enabling spectrums of the light emitted from the light source 540 to enter the processing chamber 510 through the first window 550 and be collected using the light detector 545 through the second window 555. For example, the first window 550 and the second window 555 may comprise materials that are chemical-resistant to aggressive etchants and processing solutions, and transparent to the wavelengths used in the monitoring process, such as quartz, sapphire, chemical-resistant glass, or polycarbonate or specialized plastics.

To rotate (or spin) the wafer 100 during the processing method, the processing system 500 comprises a rotary drive 530 coupled to the wafer holder 520 using a rod 532. In other embodiments, the processing system 500 comprises a spin table directly coupled to the wafer holder 520, the spin table configured to rotate the wafer 100 during processing in accordance with embodiments of this disclosure. The rotary drive 530 may be capable of rotating the wafer 100 at angular velocities between 100 RPM and 3000 RPM.

To control the pressure within the processing chamber 510, the processing system 500 comprises a vacuum pump 570 connected to the processing chamber 510 through a gate valve 572. This setup allows for precise control of the chamber pressure during the processing method. For example, the processing method may configure pressures within the processing chamber 510 using the vacuum pump 570 and the gate valve 572 between about 20 mTorr and about 90,000 mTorr. In some embodiments, the processing chamber 510 may be pressurized with a gas such as nitrogen or CO₂, where the pressure may be as high as 65 kTorr.

The entire processing system 500 may be managed by a controller 580, which may be coupled to a memory 585. The controller 580 coordinates the operation of all system components, while the memory 585 stores process recipes, parameters, and other relevant data of the processing method. The controller 580 and the memory 585 may be any suitable conventional device known in the art and capable of performing the functions described above.

In one or more embodiments, the processing system 500 is used to process the wafer 100 according to the processing methods of this disclosure. This is achieved by controlling various processing parameters during the flowing of processing solution over the wafer 100 while rotating the wafer 100. The processing parameters may comprise the nozzle height of the nozzle 110, the temperature of the wafer 100, the flow rate of processing solution from the nozzle 110 controlled by the solution dispensing system 560, the angular velocity of the wafer 100 controlled by the rotary drive 530, and the chamber pressure of the processing chamber 510 controlled by the vacuum pump 570. In some embodiments, the vacuum pump 570 may be replaced with a pressurized pump. In other embodiments, the processing system 500 may further comprise multiple nozzles, which may each have independently configurable flow rates of processing solution which may enable further variational possibilities of processing parameters to prevent hydraulic jump and improve etch uniformity of the wafer 100.

The processing system 500 may be used to implement various embodiment processing methods of this disclosure, such as the processing methods described below using the flowcharts of FIGS. 6-7 below, or the methods 300a-300b of FIGS. 3A-3B, or the processing methods described using FIG. 1A-1C or 2A-2B.

FIGS. 6-7 are flowcharts illustrating example methods of processing a wafer by modifying processing parameters during the processing to prevent hydraulic jump and improve etch uniformity in accordance with embodiments of this disclosure. The methods of FIGS. 6-7 may be combined with other methods and performed using suitable systems and apparatuses as described herein, such as the methods 300a-300b described using FIGS. 3A-3B and the processing system 500 described using FIG. 5. Although shown in a logical order, the arrangement and numbering of the steps of FIGS. 6-7 are not intended to be limiting.

Referring to FIG. 6, step 610 of a method 600 of processing a wafer receives the wafer on a wafer holder disposed in a processing chamber comprising a nozzle, the nozzle disposed over the wafer at a nozzle height. In various embodiments, the wafer may be the wafer 100 of FIG. 1A, the nozzle may be the nozzle 110 of FIG. 1A, and the processing chamber and the wafer holder may be the processing chamber 510 and the wafer holder 520 of FIG. 5, respectively.

After, the method 600 rotates the wafer at a first angular velocity in step 620. In various embodiments, the first angular velocity may be the first angular velocity (ω₁) of FIGS. 1B and 2A above. Step 630 of the method 600 dispenses a processing solution form the nozzle at a first flow rate over the wafer rotating at the first angular velocity for a processing time. In one or more embodiments, the first flow rate may be the first flow rate (Q₁) of FIGS. 1B and 2A above. Additionally, steps 620 and 630 may be the steps described using FIG. 1B, and the first flow rate and the first angular velocity may be as similarly described using those figures.

And the method 600, in step 640, during the processing time, accelerates the first angular velocity at an angular acceleration. For example, the first angular velocity may be accelerated to the second angular velocity (ω₂) of FIG. 1C. The acceleration (or change) of the processing parameter (the first angular velocity) prevents hydraulic jump and improves etch uniformity. Step 640 may be the step described using FIG. 1C above. In an embodiment, the steps of the method 600 may be the steps (310, 320, 330, and 340) of the method 300a in FIG. 3A.

Now referring to FIG. 7, step 710 of a method 700 of processing a wafer receives the wafer on a wafer holder disposed in a processing chamber comprising a nozzle, the nozzle disposed over the wafer at a nozzle height, the wafer comprising a wafer radius. After, in step 720, the method 700 processes the wafer using a first set of processing parameters for a processing time, the processing comprising rotating the wafer at a first angular velocity and flowing a processing solution over the wafer at a first flow rate, the first set of processing parameters comprising the first angular velocity and the first flow rate.

Step 730 of the method 700, during the processing time, determines whether the processing solution has formed a fluid accumulation at a radial distance less than the wafer radius using a light detector. And the method 700, in step 740, in response to determining the processing solution has formed a fluid accumulation at a radial distance less than the wafer radius, accelerates the first set of processing parameters to a second set of processing parameters during the processing time to eliminate the fluid accumulation, the second set of processing parameters comprising a second angular velocity and a second flow rate.

In various embodiments, the various steps of the method 700 may be the steps described using FIGS. 1A-1C and 2A-2B. In some embodiments, the steps of the method 700 may be the steps of the method 300b in FIG. 3B. For example, step 710 may be the step 315 of FIG. 3B or the step described using FIG. 1A. Similarly, steps 720 and 730 may be the steps 325, 335, and 335 of the method 300b of FIG. 3B and the step described using FIG. 2A. In one or more embodiments, the light detector of the method 700 may be the light detector 250 of FIGS. 2A-2B. And step 740 of the method 700 may be step 355 of the method 300b in FIG. 3B and the step described using FIG. 2B.

Example embodiments of the invention are described below. Other embodiments can also be understood from the entirety of the specification as well as the claims filed herein.

Example 1. A method for processing a wafer includes receiving the wafer on a wafer holder disposed in a processing chamber including a nozzle, the nozzle disposed over the wafer at a nozzle height. The method further includes rotating the wafer at a first angular velocity, and dispensing a processing solution from the nozzle at a first flow rate over the wafer while rotating the wafer at a varying angular velocity different from the first angular velocity during a processing time. And the method further includes, during the processing time, accelerating the wafer from the first angular velocity.

Example 2. The method of example 1, where rotating the wafer at a varying angular velocity includes accelerating the wafer from the first angular velocity at a constant angular acceleration.

Example 3. The method of one of examples 1 or 2, where rotating the wafer at a varying angular velocity includes accelerating the wafer from the first angular velocity at a sinusoidal angular acceleration.

Example 4. The method of one of examples 1 to 3, further including, during the processing time, modifying a flow rate of the processing solution from the first flow rate to a second flow rate.

Example 5. The method of one of examples 1 to 4, further including, during the processing time, modifying the nozzle height to change a distance between the nozzle and the wafer.

Example 6. The method of one of examples 1 to 5, further including dispensing a rinsing solution from the nozzle over the wafer while maintaining the rotating, the rinsing solution including deionized water, and after rinsing the wafer for a second processing time, spinning the wafer at a drying angular velocity to dry the wafer.

Example 7. The method of one of examples 1 to 6, where the processing solution includes an etchant used to etch the wafer.

Example 8. The method of one of examples 1 to 7, where the nozzle dispenses the processing solution at the first flow rate over a center of the wafer.

Example 9. The method of one of examples 1 to 8, where the processing chamber includes a second nozzle disposed over the wafer at a predetermined radial distance from the center of the wafer and at a second nozzle height, and where the second nozzle is configured to dispense processing solution over the wafer at a second flow rate.

Example 10. A method for processing a wafer includes receiving the wafer on a wafer holder disposed in a processing chamber including a nozzle, the nozzle disposed over the wafer at a nozzle height, the wafer including a wafer radius. The method further includes processing the wafer using a first set of processing parameters during a processing time, the processing including rotating the wafer at a first angular velocity and flowing a processing solution over the wafer at a first flow rate, the first set of processing parameters including the first angular velocity and the first flow rate. The method further includes, during the processing time, determining whether the processing solution has formed a fluid accumulation at a radial distance less than the wafer radius using a light detector. And the method further includes, in response to determining the processing solution has formed a fluid accumulation at a radial distance less than the wafer radius, accelerating the wafer from the first set of processing parameters to a second set of processing parameters during the processing time, the second set of processing parameters including a second angular velocity different from the first angular velocity and a second flow rate different from the first flow rate.

Example 11. The method of example 10, where the second set of processing parameters are determined based on the radial distance of the fluid accumulation measured by the light detector.

Example 12. The method of one of examples 10 or 11, further including, in response to determining the processing solution has formed a fluid accumulation at a radial distance less than the wafer radius, modifying the nozzle height to change a distance between the nozzle and the wafer.

Example 13. The method of one of examples 10 to 12, further including dispensing a rinsing solution from the nozzle over the wafer while maintaining the second angular velocity for a second processing time, and after rinsing the wafer for the second processing time, spinning the wafer at a third angular velocity to dry the wafer, the third angular velocity being higher than the second angular velocity.

Example 14. The method of one of examples 10 to 13, where the first angular velocity is accelerated to the second angular velocity using an angular acceleration, the angular acceleration being a constant.

Example 15. The method of one of examples 10 to 14, where the first angular velocity is accelerated to the second angular velocity using an angular acceleration, the angular acceleration being sinusoidal.

Example 16. The method of one of examples 10 to 15, where the accelerating the wafer from the first set of processing parameters to a second set of processing parameters during the processing time dissipates the fluid accumulation at the radial distance less than the wafer radius.

Example 17. A system for processing a wafer includes a wafer holder disposed in a processing chamber, the processing chamber including a first window and a second window, a nozzle disposed at a configurable height over the wafer holder in the processing chamber, a light source and a light detector, the light source coupled to the first window and the light detector coupled to the second window, and a rotary drive coupled to the wafer holder. And the system further includes a controller coupled to the nozzle, the processing chamber, the light source, the light detector, the rotary drive, the wafer holder, and a memory storing instructions to be executed in the controller. The instructions when executed enable the controller to receive the wafer on the wafer holder, the nozzle disposed over the wafer at a nozzle height, the wafer including a wafer radius, and process the wafer using a first set of processing parameters during a processing time in the processing chamber, the processing including rotating the wafer at a first angular velocity using the rotary drive and flowing a processing solution from the nozzle over the wafer at a first flow rate, the first set of processing parameters including the first angular velocity and the first flow rate. The instructions when executed further enable the controller to, during the processing time, determine whether the processing solution has formed a fluid accumulation at a radial distance less than the wafer radius using the light detector, and in response to determining the processing solution has formed a fluid accumulation at a radial distance less than the wafer radius, accelerate the wafer from the first set of processing parameters to a second set of processing parameters during the processing time using the nozzle and the rotary drive, the second set of processing parameters including a second angular velocity different from the first angular velocity and a second flow rate different from the first flow rate.

Example 18. The system of example 17, where the light detector includes a high-speed camera, where the processing chamber includes an etch chamber, and where the processing solution includes an etchant used to etch the wafer.

Example 19. The system of one of examples 17 or 18, further including a second nozzle disposed over the wafer holder.

Example 20. The system of one of examples 17 to 19, further including a vacuum pump or a pressurized pump coupled to the processing chamber.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for processing a wafer, the method comprising:
receiving the wafer on a wafer holder disposed in a processing chamber comprising a nozzle, the nozzle disposed over the wafer at a nozzle height;
rotating the wafer at a first angular velocity;
dispensing a processing solution from the nozzle at a first flow rate over the wafer while rotating the wafer at a varying angular velocity different from the first angular velocity during a processing time; and
during the processing time, accelerating the wafer from the first angular velocity.

2. The method of claim 1, wherein rotating the wafer at a varying angular velocity comprises accelerating the wafer from the first angular velocity at a constant angular acceleration.

3. The method of claim 1, wherein rotating the wafer at a varying angular velocity comprises accelerating the wafer from the first angular velocity at a sinusoidal angular acceleration.

4. The method of claim 1, further comprising, during the processing time, modifying a flow rate of the processing solution from the first flow rate to a second flow rate.

5. The method of claim 1, further comprising, during the processing time, modifying the nozzle height to change a distance between the nozzle and the wafer.

6. The method of claim 1, further comprising:
dispensing a rinsing solution from the nozzle over the wafer while maintaining the rotating, the rinsing solution comprising deionized water; and
after rinsing the wafer for a second processing time, spinning the wafer at a drying angular velocity to dry the wafer.

7. The method of claim 1, wherein the processing solution comprises an etchant used to etch the wafer.

8. The method of claim 1, wherein the nozzle dispenses the processing solution at the first flow rate over a center of the wafer.

9. The method of claim 8, wherein the processing chamber comprises a second nozzle disposed over the wafer at a predetermined radial distance from the center of the wafer and at a second nozzle height, and wherein the second nozzle is configured to dispense processing solution over the wafer at a second flow rate.

10. A method for processing a wafer, the method comprising:
receiving the wafer on a wafer holder disposed in a processing chamber comprising a nozzle, the nozzle disposed over the wafer at a nozzle height, the wafer comprising a wafer radius;
processing the wafer using a first set of processing parameters during a processing time, the processing comprising rotating the wafer at a first angular velocity and flowing a processing solution over the wafer at a first flow rate, the first set of processing parameters comprising the first angular velocity and the first flow rate;
during the processing time, determining whether the processing solution has formed a fluid accumulation at a radial distance less than the wafer radius using a light detector; and
in response to determining the processing solution has formed a fluid accumulation at a radial distance less than the wafer radius, accelerating the wafer from the first set of processing parameters to a second set of processing parameters during the processing time, the second set of processing parameters comprising a second angular velocity different from the first angular velocity and a second flow rate different from the first flow rate.

11. The method of claim 10, wherein the second set of processing parameters are determined based on the radial distance of the fluid accumulation measured by the light detector.

12. The method of claim 10, further comprising, in response to determining the processing solution has formed a fluid accumulation at a radial distance less than the wafer radius, modifying the nozzle height to change a distance between the nozzle and the wafer.

13. The method of claim 10, further comprising:
dispensing a rinsing solution from the nozzle over the wafer while maintaining the second angular velocity for a second processing time; and
after rinsing the wafer for the second processing time, spinning the wafer at a third angular velocity to dry the wafer, the third angular velocity being higher than the second angular velocity.

14. The method of claim 10, wherein the first angular velocity is accelerated to the second angular velocity using an angular acceleration, the angular acceleration being a constant.

15. The method of claim 10, wherein the first angular velocity is accelerated to the second angular velocity using an angular acceleration, the angular acceleration being sinusoidal.

16. The method of claim 10, wherein the accelerating the wafer from the first set of processing parameters to a second set of processing parameters during the processing time dissipates the fluid accumulation at the radial distance less than the wafer radius.

17. A system for processing a wafer, the system comprising:
a wafer holder disposed in a processing chamber, the processing chamber comprising a first window and a second window;
a nozzle disposed at a configurable height over the wafer holder in the processing chamber;
a light source and a light detector, the light source coupled to the first window and the light detector coupled to the second window;
a rotary drive coupled to the wafer holder; and
a controller coupled to the nozzle, the processing chamber, the light source, the light detector, the rotary drive, the wafer holder, and a memory storing instructions to be executed in the controller, the instructions when executed enable the controller to:
receive the wafer on the wafer holder, the nozzle disposed over the wafer at a nozzle height, the wafer comprising a wafer radius;
process the wafer using a first set of processing parameters during a processing time in the processing chamber, the processing comprising rotating the wafer at a first angular velocity using the rotary drive and flowing a processing solution from the nozzle over the wafer at a first flow rate, the first set of processing parameters comprising the first angular velocity and the first flow rate;
during the processing time, determine whether the processing solution has formed a fluid accumulation at a radial distance less than the wafer radius using the light detector; and
in response to determining the processing solution has formed a fluid accumulation at a radial distance less than the wafer radius, accelerate the wafer from the first set of processing parameters to a second set of processing parameters during the processing time using the nozzle and the rotary drive, the second set of processing parameters comprising a second angular velocity different from the first angular velocity and a second flow rate different from the first flow rate.

18. The system of claim 17, wherein the light detector comprises a high-speed camera, wherein the processing chamber comprises an etch chamber, and wherein the processing solution comprises an etchant used to etch the wafer.

19. The system of claim 17, further comprising a second nozzle disposed over the wafer holder.

20. The system of claim 17, further comprising a vacuum pump or a pressurized pump coupled to the processing chamber.
